(19) United States
(12) Patent Application Publication
(10) Pub. No.: US 2014/0283903 A1
(43) Pub. Date: Sep. 25, 2014

(54) Photovoltaic Semiconductor Chip

(71) Applicant: OSRAM OPTO SEMICONDUCTORS GMBH, Regensburg (DE)

(72) Inventors: Norwin von Malm, Nittendorf (DE); Hans-Juergen Lugauer, Sinzing (DE)

(73) Assignee: OSRAM OPTO SEMICONDUCTORS GMBH, Regensburg (DE)

(21) Appl. No.: 14/347,391

(22) PCT Filed: Sep. 27, 2012
(86) PCT No.: PCT/EP2012/069124

§ 371 Date: Mar. 26, 2014

(30) Foreign Application Priority Data
Sep. 28, 2011 (DE) 10 2011 115 659.7

(51) Int. Cl. H01L 31/0352; H01L 31/0725

(52) U.S. Cl. CPC H01L 31/035272; H01L 31/0725
USPC 136/255

(57) ABSTRACT

A photovoltaic semiconductor chip comprising a semiconductor body which comprises a semiconductor layer sequence with an active region provided to generate electrical energy. The active region is formed between a first semiconductor layer of a first conductivity type and a second semiconductor layer of a second conductivity type different from the first conductivity type. The semiconductor body is disposed on a carrier body. The first semiconductor layer is disposed on the side of the second semiconductor layer facing away from the carrier body. The semiconductor body comprises a recess which extends from the carrier body through the second semiconductor layer. A first connection structure is disposed between the carrier body and the semiconductor body and is connected in an electrically conductive manner in the recess to the first semiconductor layer.

This patent application is a national phase filing under section 371 of PCT/EP2012/069124, filed Sep. 27, 2012, which claims the priority of German patent application 10 2011 115 659.7, filed Sep. 28, 2011, each of which is incorporated herein by reference in its entirety.

### TECHNICAL FIELD

The present application relates to a photovoltaic semiconductor chip.

For efficient operation of semiconductor chips for photovoltaics, the generated charge carriers must be discharged in the most effective manner possible. In particular, in the case of concentrated photovoltaics with solar radiation concentrated 1000 times or more, the current densities to be discharged can become extremely high and be, for example, in a range of 30-50 A/cm².

### SUMMARY OF THE INVENTION

Embodiments of the invention provide a semiconductor chip with efficient charge carrier transport and a high level of efficiency in energy generation.

In one embodiment a photovoltaic semiconductor chip comprises a semiconductor body with a semiconductor layer sequence. The semiconductor layer sequence comprises an active region which is provided to generate electrical energy and is formed between a first semiconductor layer of a first conductivity type and a second semiconductor layer of a second conductivity type different from the first conductivity type. The semiconductor body with the semiconductor layer sequence is disposed on a carrier body. The first semiconductor layer is disposed on the side of the second semiconductor layer facing away from the carrier body. The semiconductor body with the semiconductor layer sequence comprises at least one recess which extends from the carrier body through the second semiconductor layer. At least in regions a first connection structure is disposed between the carrier body and the semiconductor body and is electrically connected in the recess to the first semiconductor layer.

A photovoltaic semiconductor chip is understood in particular to be a semiconductor chip in which, when irradiated with electromagnetic radiation, in particular solar radiation, charge carrier pairs, i.e., electrons and holes, generated in the active region by radiation absorption, are spatially separated, which means that an electrical voltage falls at external contacts of the semiconductor chip.

The first connection structure is formed outside the semiconductor body and is also provided for electrically contacting the first semiconductor layer from a main surface of the semiconductor body facing towards the carrier body. A main surface of the semiconductor body facing away from the carrier body can be free of electrical contacts. The risk of efficiency-reducing shading of the active region by radiation-impermeable contact layers can thus be avoided.

Upon entry of electromagnetic radiation, in particular concentrated solar radiation, charge carriers, generated in the active region, of the first conductivity type, i.e., electrons in the case of an n-conducting first semiconductor layer or holes in the case of a p-conducting first semiconductor layer, can be discharged via the first connection structure. The semiconductor body preferably comprises a plurality of recesses, in which the first semiconductor layer is connected in each case to the first connection structure. The higher the number of recesses, the smaller the average distance can be which generated charge carriers must travel in the first semiconductor layer before they reach one of the recesses.

The first connection structure in the recess expediently directly adjoins the first semiconductor layer.

In order to avoid an electrical short-circuit the first connection structure is expediently electrically insulated from the second semiconductor layer, in particular in the region of the recess.

The second semiconductor layer is preferably connected in an electrically conductive manner to a second connection structure. The second connection structure is preferably disposed between the semiconductor body and the carrier body. The first connection structure and also the second connection structure can thus be formed in regions between the semiconductor body and the carrier body.

The second connection structure is provided for the discharge of charge carriers from the second semiconductor layer. The second connection structure directly adjoins, preferably at least in regions, a semiconductor material of the second conductivity type, i.e., of the conductivity type of the second semiconductor layer. The second semiconductor layer can directly adjoin the second connection structure or can be connected to the second connection structure in an electrically conductive manner via intermediate layers, in particular via further layers of the semiconductor body.

In a preferred development, the second connection structure overlaps with the first connection structure when the semiconductor chip is seen in a top view. In particular, in a top view of the semiconductor chip, the sum of the surface of the carrier body covered by the first connection structure and of the surface of the carrier body covered by the second connection structure can exceed the total surface of the carrier body.

The first connection structure and the second connection structure can thus be formed with a large surface area, which means that charge carrier removal under radiation can take place in a particularly efficient manner.

In a preferred development the second connection structure is disposed in regions between the first connection structure and the semiconductor body. In particular, the second connection structure can directly adjoin the semiconductor body. Preferably at least 50%, particularly preferably at least 70%, of the main surface of the semiconductor body facing towards the carrier body is covered with the second connection structure.

Also in a preferred manner, the second connection structure comprises a mirror layer. The mirror layer is provided to reflect the portion of the incident radiation passing through the semiconductor body back into the semiconductor body. The reflectivity of the mirror layer at least in a wavelength range of the spectral range to be absorbed preferably amounts to at least 50%, in a particularly preferred manner at least 70%.

By means of the mirror layer the portion of the solar radiation not absorbed during single passage can be reflected back into the semiconductor body. By reason of the at least double passage through the semiconductor body an equally high level of overall absorption may be achieved even with thinner semiconductor layers.

Such thin semiconductor layers can be doped to a comparatively high level without the associated reduced charge carrier mobility having a negative impact on the efficiency of the photovoltaic semiconductor chip. A higher doping concentration also brings about a greater open-circuit voltage (V_{OC}).

Furthermore, radiation absorption in the carrier body can be avoided by the mirror layer.

In a further preferred embodiment, the semiconductor chip is free of a growth substrate for the semiconductor layer sequence of the semiconductor body. The carrier body serves for mechanical stabilization of the semiconductor layer sequence of the semiconductor body. After the preferably epitaxial deposition of the semiconductor layer sequence on the growth substrate, this substrate is no longer necessary and can therefore be completely removed or else be thinned or removed only in regions. The carrier body thus does not have to fulfil the high crystalline requirements of a growth substrate but can be selected with respect to other properties, for example, high thermal and/or electrical conductivity and/or high mechanical stability.

In a preferred embodiment, the semiconductor body contains a III-V compound semiconductor material.

III-V compound semiconductor materials are particularly suitable for radiation absorption of radiation in the infrared, visible and ultraviolet spectral range. For example, with nitride semiconductor material, in particular with AlₓIn_{y}Ga_{1-x-y}N, a cut-off wavelength corresponding to the band-gap in the ultraviolet, blue or green spectral range can be achieved. Phosphide semiconductor material, in particular AlₓIn_{y}Ga_{1-x-y}P, is suitable for a cut-off wavelength in the yellow to red spectral range, arsenide semiconductor material, in particular AlₓIn_{y}Ga_{1-x-y}As, is suitable for a cut-off wavelength in the red and infrared AlₓIn_{y}Ga_{1-x-y}As spectral range. In this case 0≦x≦1, 0≦y≦1 and x+y≦1 applies respectively, in particular with x≠1, y≠1, x≠0 and/or y≠0.

In a further preferred embodiment, a second active region provided to generate electrical energy is formed between the second semiconductor layer and the carrier body. A band-gap of the second active region is preferably smaller than a band-gap of the first active region. Radiation with a wavelength which is above a cut-off wavelength corresponding to the band-gap of the first active region can thus be absorbed by the second active region and converted into electrical energy. In particular, the first active region and the second active region can be integrated monolithically into the semiconductor body. That is to say, the first active region and the second active region can be deposited one after the other in a common epitaxy step.

The number of active regions within the semiconductor body preferably amounts to between 1 and 10 inclusive. In the case of a plurality of active regions, the active regions are preferably each disposed between a first semiconductor layer of a first conductivity type and a second semiconductor layer of a second conductivity type. The first connection structure preferably directly adjoins the first semiconductor layer which is allocated to the active region which is disposed furthest away from the carrier body. In a corresponding manner, the second connection structure directly adjoins the second semiconductor layer which is allocated to the active region which lies closest to the carrier body.

The first active region and the second active region are expediently electrically connected to each other in series. In particular, between the first active region and the second active region a tunnel region can be formed. In the case of more than two active regions, a respective tunnel region is preferably disposed between two adjacent active regions.

In one embodiment variation, the recess extends completely through the semiconductor body, i.e., also completely through the first semiconductor layer. In this embodiment variation, the first semiconductor layer is preferably covered with a radiation-permeable connection layer which is connected in an electrically conductive manner to the first connection structure. The radiation-permeable connection layer preferably contains a TCO material.

Transparent conductive oxides (abbreviated as TCOs) are transparent conductive materials, generally metal oxides such as, for example, zinc oxide, tin oxide, cadmium oxide, titanium oxide, indium oxide or indium tin oxide (ITO). In addition to binary metal oxygen compounds such as, for example, ZnO, SnO₂ or In₂O₃, ternary metal oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and can also be p-doped or n-doped.

The radiation-permeable connection layer is thus disposed outside the semiconductor body. During production, it can be formed after conclusion of the epitaxy of the semiconductor layer sequence of the semiconductor body on the semiconductor body, for example, by sputtering or vapor-deposition.

By means of the radiation-permeable connection layer, a homogeneous and efficient charge carrier discharge from the first semiconductor layer can be achieved even in the case of a comparatively low electrical transverse conductivity of the first semiconductor layer and/or a short average free path length of the charge carriers in the first semiconductor layer.

In an alternative embodiment variation, the recess terminates in the first semiconductor layer, which means that the recess does not extend completely through the semiconductor body. The recess thus constitutes a blind hole.

In a further preferred embodiment, the active region is divided into a first partial region and into a second partial region spaced apart from the first partial region. The active regions of the partial regions thus emerge from the same semiconductor layer sequence during production. In a lateral direction, i.e., in a direction extending in a main plane of extension of the semiconductor layers of the semiconductor body, the first partial region and the second partial region are spaced apart from each other. The active regions of the partial regions are preferably electrically connected to each other, in particular are at least partially electrically connected in series. By means of a series connection, the voltage provided by the semiconductor chip can be increased during operation.

Alternatively or in addition, partial regions of the semiconductor chip can be electrically connected in parallel with each other. By means of a parallel connection, the electrical current available during operation can be increased.

The semiconductor chip preferably comprises a connecting region in which the first connection region of the first partial region is electrically connected to the second connection region of the second partial region. The electrical series connection is thus effected within the semiconductor chip. Expensive external connection of the individual partial regions, for example, by wire connections, may be dispensed with.

For the purposes of external electrical contacting, the semiconductor chip preferably comprises a first electrical contact and a second electrical contact. The contacts thus form the voltage poles of the photovoltaic semiconductor chip.

In one embodiment variation, at least one of the electrical contacts is disposed on a side of the carrier body facing the semiconductor body. It is also possible for both electrical contacts to be disposed on this side. Contacting of the semiconductor chip on the upper side, i.e., on the radiation entry side, is thus simplified. The upper-side contact or the upper-side contacts are in this case expediently disposed in the lateral direction next to the semiconductor body.

In other words the electrical contact or the electrical contacts and the semiconductor body are disposed on the carrier body with no overlapping. The external electrical contacting can thus be effected from the upper side of the semiconductor chip without the contacts causing any shading of the active region or of the active regions.

Alternatively or in addition, one of the electrical contacts, in particular both of the electrical contacts, can be disposed on a side of the carrier body facing away from the semiconductor body. In an arrangement with both electrical contacts on this side of the carrier body, the contacting of the semiconductor chip can take place more easily from the rear side of the semiconductor chip facing away from the radiation entry surface.

In a further preferred embodiment the first connection structure and/or the second connection structure is formed by a layer on the carrier body. During production of the semiconductor chip the first connection structure and/or the second connection structure can thus be formed at least partially on the carrier body even before the semiconductor body with the semiconductor layer sequence is attached to the carrier body. The production of the semiconductor chip can thus be simplified.

### BRIEF DESCRIPTION OF THE DRAWINGS

Further features, embodiments and expediencies will become clear from the following description of the exemplary embodiments in conjunction with the figures.

FIGS. 1A and 1B show a first exemplary embodiment of a photovoltaic semiconductor chip in a schematic cross-sectional view (FIG. 1A) and a schematic top view (FIG. 1B); and

FIGS. 2 to 5 each show a further exemplary embodiment of a photovoltaic semiconductor chip.

Identical, similar or identically acting elements are provided with the same reference numerals in the figures.

The figures and the size ratios of the elements with respect to each other as shown in the figures are not to be considered as being to scale. Rather, individual elements may be illustrated to an excessively large extent for the sake of better illustration and/or for better understanding.

### DETAILED DESCRIPTION OF ILLUSTRATIVE EMBODIMENTS

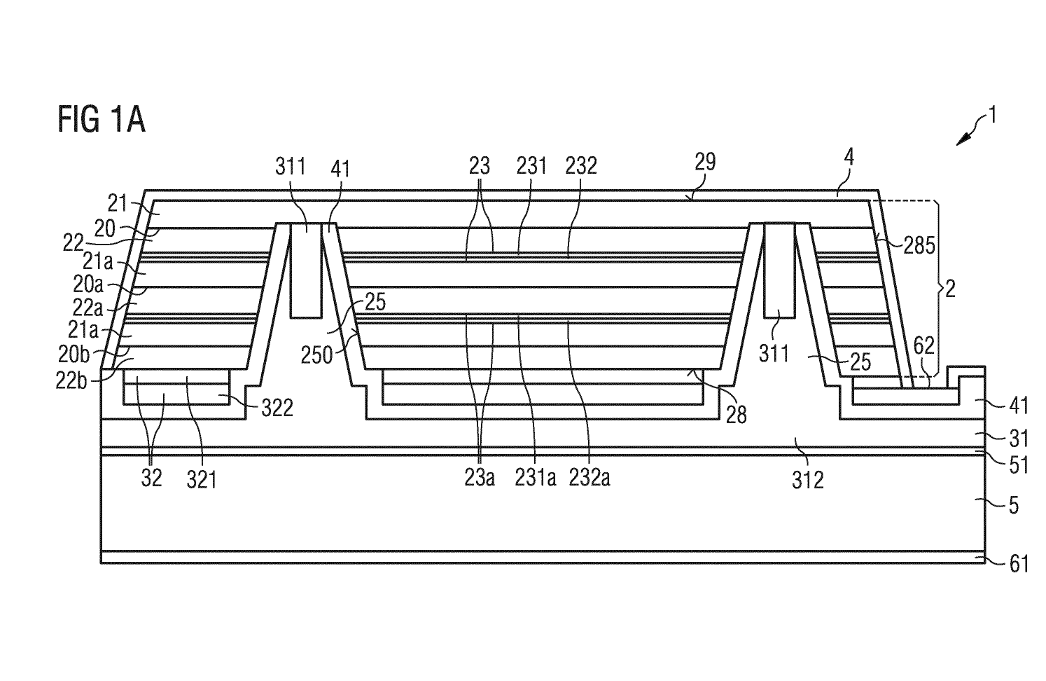

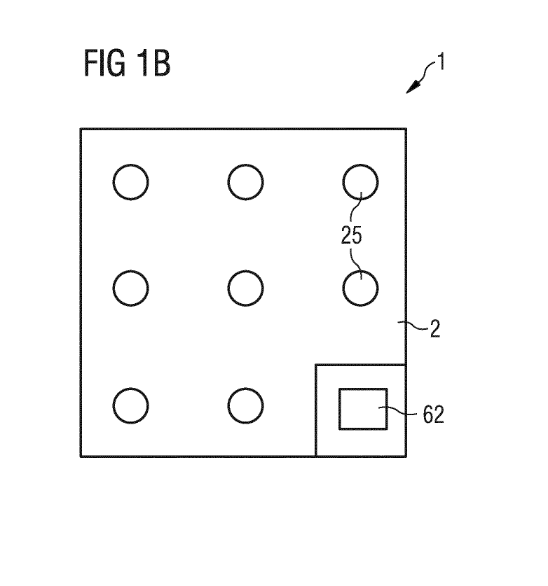

A first exemplary embodiment of a photovoltaic semiconductor chip 1 is shown in FIGS. 1A and 1B. The semiconductor chip comprises a semiconductor body 2 with a semiconductor layer sequence. The semiconductor layer sequence, which is preferably deposited epitaxially, such as by MBE or MOVPE, forms the semiconductor body. In a vertical direction, i.e., in a direction extending perpendicular to a main plane of extension of the semiconductor layers of the semiconductor body 2, the semiconductor body extends between a main surface 28 and a radiation entry surface 29.

As far as the main surface 28 is concerned, the semiconductor body 2 is disposed on a carrier body 5. The semiconductor body 2 is connected to the carrier body 5 in an electrically conductive manner by a connecting layer 51, for example, a solder or an electrically conductive adhesive layer.

In the illustrated exemplary embodiment, the semiconductor body 2 comprises, by way of example, three active regions 20, 20a, 20b stacked one on top of the other. The active regions are each disposed between a first semiconductor layer 21, 21a, 21b and a second semiconductor layer 22, 22a, 22b. The first semiconductor layers can be formed in an n-conducting manner and the second semiconductor layers can be formed in a p-conducting manner or vice versa.

The active regions can each be formed by a pn-transition or by an intrinsic, i.e., undoped, semiconductor layer between the first semiconductor layer 21, 21a, 21b and the associated second semiconductor layer 22, 22a, 22b.

Between every two adjacent active regions a tunnel region 23, 23a is disposed. The tunnel regions each comprise a first semiconductor layer of a first conductivity type 231, 231a and a second layer of a second conductivity type 232, 232a. The layers of the tunnel region are preferably formed in a highly doped manner, i.e., with a doping of at least 1*10¹⁹ cm⁻³. The active regions are electrically connected in series by the tunnel regions.

The semiconductor body 2 comprises a plurality of recesses 25 which extend from the main surface 28 into the semiconductor body 2. The recesses 25 extend through all active regions of the semiconductor body and extend into the first semiconductor layer 21 of the semiconductor body 2, which lies closest to the radiation entry surface 29. In the illustrated exemplary embodiment, the first connection structure 31 is formed by a first layer 311, adjoining the first semiconductor layer 21, and of a second layer 312. In a departure therefrom, however, a single-layer embodiment may also be expedient.

By means of the first connection structure 31 the first semiconductor layer 21 is connected in an electrically conductive manner to a first electrical contact 61 via the connecting layer 51 and the carrier body 5.

A side surface 250 of the recesses 25 is covered by an insulation layer 41 at least in the region of the active regions 20, 20a, 20b and of the second semiconductor layers 22, 22a, 22b. An electrical short-circuit of the active regions via the first connection structure 31 can thus be avoided.

The second semiconductor layer 22b which lies closest to the carrier body 5 is connected in an electrically conductive manner to a second connection structure 32. Preferably, the second connection structure 32 directly adjoins the second semiconductor layer 20b over a large surface, that is to say, with a surface coverage of at least 50%.

The second connection structure 32 extends in regions between the first connection structure 31 and the semiconductor body 2. Both the first connection structure 31 and also the second connection structure 32 can thus cover the carrier body 5 over a large surface, in particular with a surface portion of more than 50% in each case. An efficient charge carrier discharge of the charge carriers separated in the active regions can thus take place in a particularly efficient manner.

The second connection structure 32 comprises in this exemplary embodiment a first layer 321 and a second layer 322. In a departure therefrom, the second connection structure can, however, also be formed with only a single layer or comprise more than two layers. The second connection structure preferably comprises a layer which is formed as a mirror layer for the radiation to be absorbed in the active regions 20, 20a, 20b. In particular, the first layer 321 adjoining the semiconductor body 2 can be formed as a mirror layer. For reduced contact resistance, however, it may also be expedient to form the second layer as a mirror layer and to form the first layer as a radiation-permeable layer which serves predominantly for electrical contact. The reflectivity of the mirror layer for radiation in the visible spectral range preferably amounts to at least 50%, in a particularly preferred manner to at least 70%. The mirror layer of the second connection structure preferably contains silver, aluminum, rhodium, palladium, gold, chromium or nickel or a metal alloy with at least one of the said materials.

A region of the second connection region 32 disposed laterally to the side of the semiconductor body 2 forms a second external contact 62. When the photovoltaic semiconductor chip 1 is irradiated, for example, by concentrated solar radiation, an electrical voltage can be tapped at the contacts 61, 62.

The radiation entry surface 29 and a side surface 285 defining the semiconductor body 2 in the lateral direction are covered with a passivation layer 4. The passivation layer 4 protects the semiconductor body from external influences such as moisture and also serves to prevent an electrical short-circuit of the active regions 20, 20a, 20b.

During production, the side surface 285 can be formed by a structuring process. In particular the structuring can take place in the wafer composite after the semiconductor layer sequence, from which the semiconductor bodies come, has already been attached to a carrier from which the carrier bodies are formed during division into semiconductor chips. Alternatively, the side surfaces 285 can be formed before the semiconductor layer sequence is connected to the carrier.

In particular a dielectric, radiation-permeable material such as an oxide, for example, silicon oxide, or a nitride, for example, silicon nitride, is suitable for the passivation layer.

The semiconductor body 2 is preferably based on a III-V compound semiconductor material. The band gaps of the active regions 20, 20a, 20b are formed such that the band gaps diminish with increasing distance from the radiation entry surface 29. Radiation with a wavelength which is above the cut-off wavelength of the active region lying closest to the radiation entry surface and is therefore not absorbed thereby can be absorbed by one of the active regions disposed downstream and thus contribute to the generation of the electrical energy.

The radiation entry surface 29 of the semiconductor body 2 is completely free of external electrical, in particular, radiation-impermeable metal contact structures, which means that shading of the active regions 20, 20a, 20b can be avoided.

A growth substrate for the semiconductor layer sequence of the semiconductor body 2 is completely removed and thus not shown in FIG. 1A. The carrier body 5 takes over the function of mechanical stabilization of the semiconductor layer sequence of the semiconductor body 2, so that the growth substrate is no longer required for this purpose.

A semiconductor material such as germanium or silicon, for example, is suitable for the carrier body 5. The semiconductor material can be doped to increase the electrical conductivity.

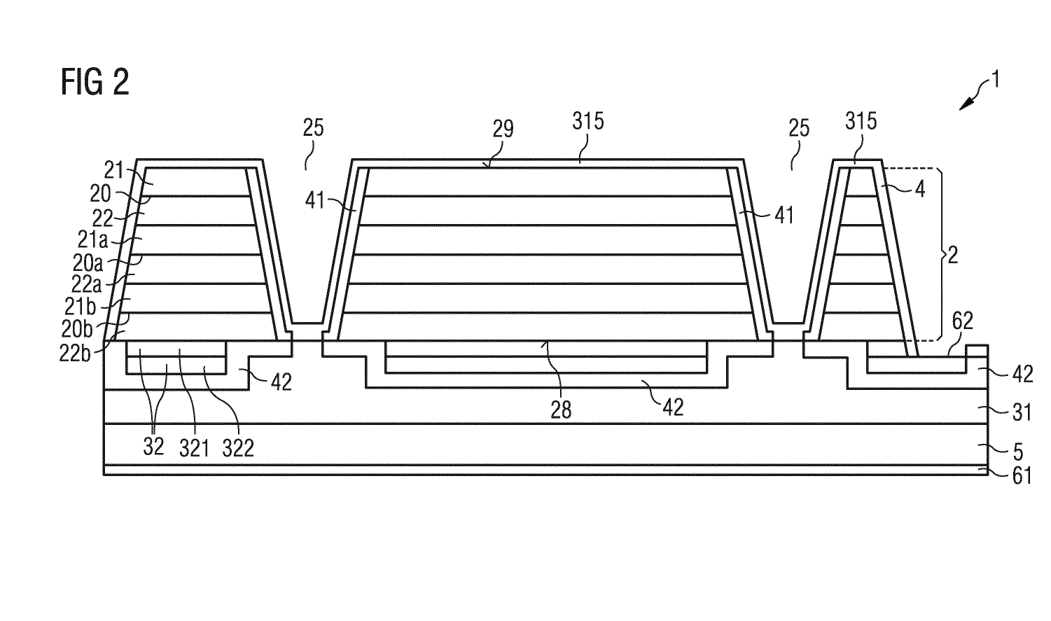

The second exemplary embodiment shown in a cross-sectional view in FIG. 2 corresponds essentially to the first exemplary embodiment described in conjunction with FIGS. 1A and 1B. In contrast thereto, the recesses 25 are formed in such a way that they extend completely through the semiconductor body 2. In a top view of the semiconductor chip, the recesses 25, as shown in FIG. 1B, are formed in such a way that the semiconductor layers of the semiconductor body 2 constitute semiconductor layers which are contiguous in spite of the recesses 25.

Furthermore, the semiconductor chip 2 comprises a radiation-permeable connection layer 315 on the radiation entry surface 29, which connection layer is connected in an electrically conductive manner to the first connection structure 31 in the region of the recesses 25. In particular a TCO material, for example, ITO or ZnO, is suitable for the radiation-permeable connection layer. However, another TCO material of those mentioned in the general part of the description can also be used.

Furthermore, in contrast to the first exemplary embodiment illustrated in FIG. 1A, the recesses 25 have a cross-section which tapers towards the carrier body 5. Recesses of this type can be formed, for example, by a wet chemical or dry chemical process after the semiconductor layer sequence of the semiconductor body 2 has already been attached to the carrier body 5 and the growth substrate for the semiconductor layer sequence has been removed. In a departure from the described exemplary embodiment, the side surfaces of the recesses 25 can, however, also extend perpendicularly. A cross-section for the recesses 25 which increases in size towards the carrier body 5 can also be used.

The electrical insulation between the first connection structure 31 and the second connection structure 32 is created by a second insulation layer 42 between these connection structures.

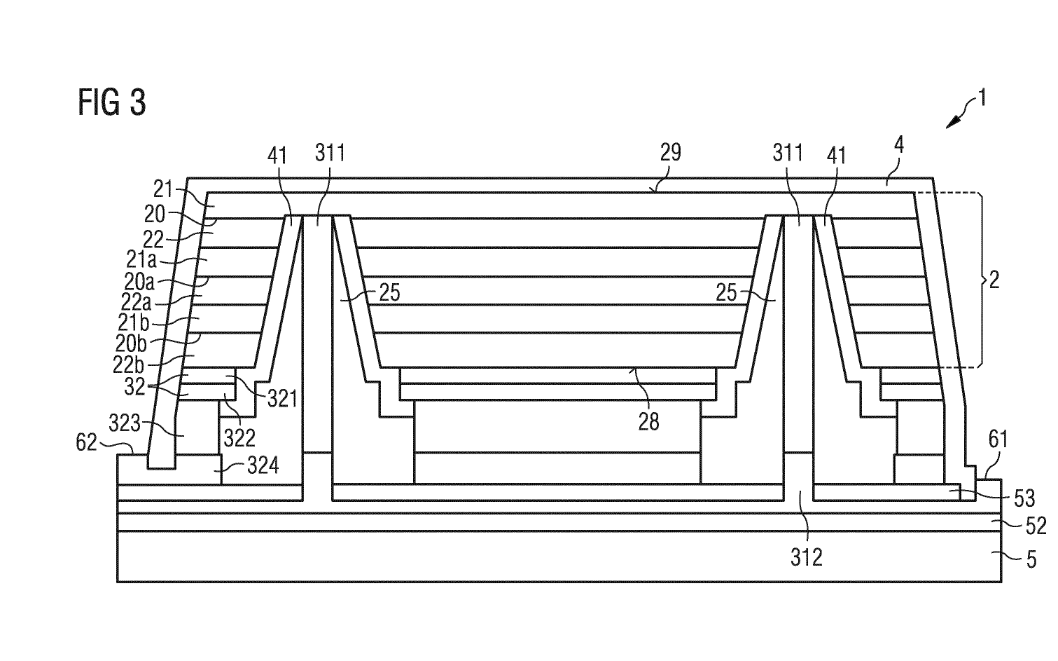

A further exemplary embodiment for a photovoltaic semiconductor chip 1 is illustrated schematically in FIG. 3. This third exemplary embodiment corresponds essentially to the first exemplary embodiment described in conjunction with FIGS. 1A and 1B.

In contrast thereto, the first contact 61 and the second contact 62 are disposed on the side of the carrier body 5 facing towards the semiconductor body 2. Both contacts are thus accessible from the upper side of the semiconductor chip. In a top view of the semiconductor chip, both contacts are disposed with no overlap with the semiconductor body 2 on the carrier body, which means that shading of the radiation entry surface 29 by the contacts can be avoided. An arrangement of the contacts such as this is also suitable in particular for the exemplary embodiments described in conjunction with the FIGS. 1A, 1B and 2. In this exemplary embodiment an electrically conductive material can be used for the carrier body 5 as described in conjunction with FIGS. 1A and 1B.

Alternatively, an electrically insulating material can also be used, for example, an undoped semiconductor material or a ceramic.

Furthermore, the first connection structure 31 and the second connection structure 32 are formed in regions by layers applied to the carrier body 5. In the illustrated exemplary embodiment the second layer 312 of the first connection structure 31 is formed as a layer formed on the carrier body 5. Between the second layer 312 and the carrier body 5 an insulation layer 52 is formed which electrically insulates the second layer 312 and the carrier body 5 from each other.

The second connection structure 32 is formed by a first layer 321, a second layer 322, a third layer 323 and a fourth layer 324. The fourth layer 324 is formed as a layer formed on the carrier body 5, wherein between the fourth layer 324 and the layer 312 of the first connection structure 31 a further insulation layer 53 is disposed.

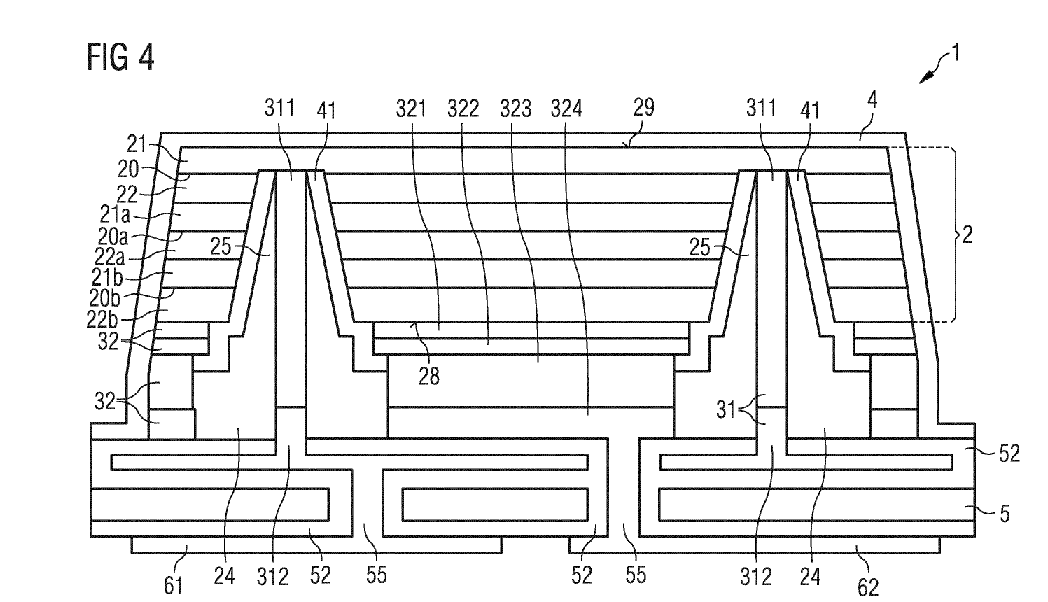

During production of the semiconductor chip, a part of the first connection structure 31 and of the second connection structure 32 can thus be formed on the carrier body 5 in an already prefabricated manner before the semiconductor body is attached with the semiconductor layer sequence 2 to the carrier body and connected in an electrically conductive manner. The fourth exemplary embodiment shown in FIG. 4 corresponds essentially to the third exemplary embodiment described in conjunction with FIG. 3.

In contrast to this, the semiconductor chip 1 is formed as a surface-mountable semiconductor chip in which both electrical contacts are located on the rear side of the semiconductor chip 1 facing away from the radiation entry surface 29. The contacts 61, 62 are thus formed on the side of the carrier body 5 facing away from the semiconductor body 2. The carrier body 5 comprises vias 55 which connect the first contact 61 in an electrically conductive manner to the first connection structure 31 and connect the second contact 62 in an electrically conductive manner to the second connection structure 32.

Furthermore, in contrast to the third exemplary embodiment, the recesses 25 are partially filled with an electrically insulating filler 24. Polyimide or BCB, for example, are particularly suitable as a filler. The mechanical stability of the semiconductor chip can be increased by the filler.

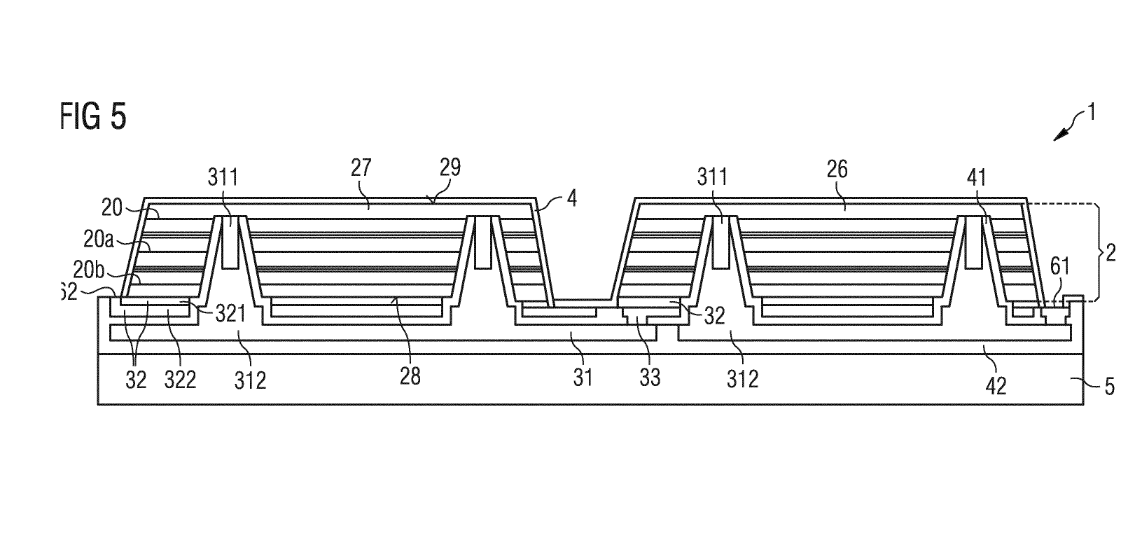

The fifth exemplary embodiment illustrated in FIG. 5 corresponds essentially to the first exemplary embodiment described in conjunction with the FIGS. 1A and 1B. In contrast to this, the semiconductor body 2 comprises at least two partial regions 26, 27. The active regions of these partial regions are completely separated from each other in the lateral direction when the semiconductor chip is seen in a top view.

In a connecting region 33, the second connection structure 32 of the first partial region 26 is electrically connected in series with the first connection structure 31 of the second partial region 27. Thus, the voltage dropping at the external electrical contacts 61, 62 during operation of the semiconductor chip 1 is the sum of the individual voltages of the partial regions 26, 27.

With the described embodiment, the operational voltage of the semiconductor chip can thus be increased, wherein the electrical connection of the partial regions takes place within the semiconductor chip. Expensive external contacting, for example, by wires, is therefore not necessary.

In the exemplary embodiment, two partial regions are shown merely by way of example. In a departure therefrom, the semiconductor chip can, however, also comprise more than two partial regions. The partial regions can be electrically connected at least partially to each other in series and/or partially in parallel with each other.

The photovoltaic semiconductor chips described in the exemplary embodiments are characterized in particular by an efficient charge carrier discharge, which means that, even in the case of high current densities, as occur in the case of concentrated solar radiation, an effective generation of electrical energy can take place. Furthermore, by the contacting via the recesses, a shading-free embodiment of the radiation entry surface of the semiconductor chip can be achieved.

The invention is not limited by the description with reference to the exemplary embodiments. It is rather the case that the invention includes each new feature and each combination of features included in particular in each combination of features in the claims, even when this feature or this combination itself is not explicitly stated in the claims or the exemplary embodiments.

1-15. (canceled)

16. A photovoltaic semiconductor chip comprising:
a carrier body;
a semiconductor body disposed on the carrier body, the semiconductor body comprising a semiconductor layer sequence with a first active region configured to generate electrical energy, wherein the first active region is disposed between a first semiconductor layer of a first conductivity type and a second semiconductor layer of a second conductivity type different from the first conductivity type, wherein
the first semiconductor layer is disposed on a side of the second semiconductor layer facing away from the carrier body, and
the semiconductor body comprises a recess extending from the carrier body through the second semiconductor layer; and
a first connection structure disposed between the carrier body and the semiconductor body, wherein the first connection structure is connected in an electrically conductive manner in the recess to the first semiconductor layer.

17. The semiconductor chip according to claim 16, wherein the second semiconductor layer is connected in an electrically conductive manner to a second connection structure.

18. The semiconductor chip according to claim 17, wherein the second connection structure is disposed between the semiconductor body and the carrier body.

19. The semiconductor chip according to claim 17, wherein the second connection structure overlaps with the first connection structure when the semiconductor chip is seen in a top view.

20. The semiconductor chip according to claim 17, wherein the second connection structure is disposed between the first connection structure and the semiconductor body.

21. The semiconductor chip according to claim 17, wherein the second connection structure comprises a mirror layer.

22. The semiconductor chip according to claim 16, wherein the semiconductor chip is free of a growth substrate for the semiconductor layer sequence of the semiconductor body.

23. The semiconductor chip according to claim 16, further comprising a second active region configured to generate electrical energy, is disposed between the second semiconductor layer and the carrier body.

24. The semiconductor chip according to claim 16, wherein the recess terminates in the first semiconductor layer.

25. The semiconductor chip according to claim 16, wherein the recess extends completely through the semiconductor body and the first semiconductor layer is covered with a radiation-permeable connection layer which is connected in an electrically conductive manner to the first connection structure.

26. The semiconductor chip according to claim 16, wherein the first active region is divided into a first partial region and into a second partial region spaced apart from the first partial region, and wherein the partial regions are electrically connected in series.

27. The semiconductor chip according to claim 16, wherein the semiconductor chip comprises a first electrical contact and a second electrical contact and one of the electrical contacts is disposed on a side of the carrier body facing towards the semiconductor body.

28. The semiconductor chip according to claim 16, wherein the semiconductor chip comprises a first electrical contact and a second electrical contact and the electrical contacts are disposed on a side of the carrier body facing away from the semiconductor body.

29. The semiconductor chip according to claim 16, wherein the first connection structure or a second connection structure is formed by a layer on the carrier body.

30. The semiconductor chip according to claim 16, wherein the semiconductor body contains a III-V compound semiconductor material.

31. A photovoltaic semiconductor chip comprising:
a carrier body;
a semiconductor body disposed on the carrier body, the semiconductor body comprising a semiconductor layer sequence with an active region configured to generate electrical energy, wherein the active region is disposed between a first semiconductor layer of a first conductivity type and a second semiconductor layer of a second conductivity type different from the first conductivity type, wherein
the first semiconductor layer is disposed on a side of the second semiconductor layer facing away from the carrier body, wherein
the semiconductor body comprises a recess which extends from the carrier body through the second semiconductor layer;
a first connection structure disposed between the carrier body and the semiconductor body and connected in an electrically conductive manner in the recess to the first semiconductor layer; and
a second connection structure connected in an electrically conductive manner to the second semiconductor layer, wherein the second connection structure is disposed between the semiconductor body and the carrier body, wherein
the second connection structure overlaps with the first connection structure when the semiconductor chip is seen in a top view, wherein
the second connection structure is disposed in regions between the first connection structure and the semiconductor body; and
an insulation layer arranged between the first connection structure and the second connection structure,
wherein the semiconductor chip is configured to generate
charge carrier pairs in the active region by radiation absorption, and further configured to spatially separated and discharged the charge carrier pairs via the first connection structure and the second connection structure.
